(19) United States
(12) Patent Application Publication
(10) Pub. No.: US 2026/0066214 A1
(43) Pub. Date: Mar. 5, 2026

(54) APPARATUS FOR A CHARGED PARTICLE BEAM DEVICE, CHARGED PARTICLE BEAM DEVICE, METHOD OF ANALYZING A MAGNETIC LENS FOR A CHARGED PARTICLE BEAM DEVICE, AND NON-TRANSITORY MEDIUM

(71) Applicant: ICT Integrated Circuit Testing Gesellschaft für Halbleiterprüftechnik mbH, Heimstetten (DE)

(72) Inventors: John Breuer, München (DE); Hanno Kaupp, Erding (DE); Markus Singer, München (DE); Gadi Oron, Rehovot (IL); Tamir Idan, Herzlyia (IL)

(73) Assignee: ICT Integrated Circuit Testing Gesellschaft für Halbleiterprüftechnik mbH, Heimstetten (DE)

(21) Appl. No.: 18/819,245

(22) Filed: Aug. 29, 2024

(51) Int. Cl. H01J 37/141

(52) U.S. Cl. CPC H01J 37/141

(57) ABSTRACT

An apparatus for a charged particle beam device is described. The charged particle beam device includes: a magnetic lens with a coil carrier; at least one pole piece; and an electrical insulator configured to electrically insulate the coil carrier and the at least one pole piece from each other.

### TECHNICAL FIELD

Embodiments of the present disclosure relate to leakage testing of components of a charged particle beam device, and particularly a magnetic lens of a charged particle beam device. Specifically, embodiments of the present disclosure relate to an apparatus for a charged particle beam device, a charged particle beam device, a method for analyzing a magnetic lens of a charged particle beam device, and an according computer program.

### BACKGROUND

Charged particle beam apparatuses have many functions, in a plurality of industrial fields, including, but not limited to, critical dimensioning of semiconductor devices during manufacturing, defect review of semiconductor devices during manufacturing, inspection of semiconductor devices during manufacturing, exposure systems for lithography, detecting devices and testing systems. Thus, there is a high demand for structuring, testing and inspecting specimens or samples within the micrometer and nanometer scale.

Micrometer and nanometer scale process control, inspection or structuring is often done with charged particle beams, e.g. electron beams, which are generated and focused in charged particle beam devices, such as electron microscopes or electron beam pattern generators. Charged particle beams offer superior spatial resolution compared to, e.g. photon beams due to their short wavelengths.

A charged particle beam device, particularly a scanning charged particle beam device, includes an objective lens focusing the primary charged particle beam emitted by an emitter on a specimen. A charged particle beam device may also include other lenses such as condenser lenses. For a scanning charged particle beam device, the spot size of the primary charged particle beam on the specimen influences the resolution of the scanning charged particle beam device. The objective lens can include a magnetic lens. The magnetic lens may include a coil, e.g. a wire arranged in a certain winding arrangement. The coil may be configured for generating the magnetic field of the magnetic lens. The coil can be water-cooled. Water-cooling of the lens improves the range of available currents for operating the magnetic lens. Water-cooling may additionally reduce thermal drifts when switching between different currents. Water-cooling may also be integrated for other types of lenses of a charged particle beam device for similar reasons. However, the water-cooling may negatively influence the reliability, for example due to leakage.

The reliable functioning of the magnetic lens may be beneficial to enable a reliable functioning of the charged particle beam device.

### SUMMARY

In light of the above, an apparatus for a charged particle beam device, a charged particle beam device, and a method for analyzing a magnetic lens of a charged particle beam device, and an according computer program are provided. Further aspects, advantages, and features are apparent from the dependent claims, the description, and the accompanying drawings.

According to a first aspect, an apparatus for a charged particle beam device is provided. The charged particle beam device includes: a magnetic lens, comprising: a coil carrier; at least one pole piece; and an electrical insulator configured to electrically insulate the coil carrier and the at least one pole piece from each other.

According to a second aspect, a charged particle beam device is provided, the charged particle beam device including an apparatus according to the first aspect.

According to a third aspect, a method of analyzing a magnetic lens for a charged particle beam device is provided. The method includes: measuring at least one electrical characteristic selected from: a resistivity between a coil carrier and at least one pole piece from the magnetic lens; a conductance between the coil carrier and the at least one pole piece; a capacitance between the coil carrier and the at least one pole piece; and an inductance between the coil carrier and the at least one pole piece.

According to a fourth aspect, a non-transitory medium is provided. The non-transitory medium includes instructions, that, when executed, cause one or more processors to perform a method according to the third aspect.

### BRIEF DESCRIPTION OF THE DRAWINGS

So that the manner in which the above recited features can be understood in detail, a more particular description, briefly summarized above, may be had by reference to embodiments. The accompanying drawings relate to embodiments and are described in the following:

FIG. 1 shows a schematic cross-sectional view of a magnetic lens according to embodiments of the present disclosure;

FIG. 2 shows a schematic cross-sectional view of a magnetic lens according to further embodiments of the present disclosure;

FIG. 3 shows a schematic cross-sectional view of a charged particle beam device including a magnetic lens according to embodiments of the present disclosure; and

FIG. 4 shows a block diagram of a method for analyzing a magnetic lens of a charged particle beam device according to an embodiment of the present disclosure.

### DETAILED DESCRIPTION OF EMBODIMENTS

Reference will now be made in detail to the various embodiments, one or more examples of which are illustrated in the figures.

Within the following description of the drawings, the same reference numbers refer to same components. Generally, only the differences with respect to individual embodiments are described. Each example is provided by way of explanation and is not meant as a limitation. Further, features illustrated or described as part of one embodiment can be used on, or in conjunction with, other embodiments to yield yet a further embodiment. It is intended that the description includes such modifications and variations.

Without limiting the scope of protection of the present application, in the following, the charged particle beam device or components thereof may be exemplarily referred to as an electron beam device, including the detection signal electrons such as of secondary electrons and/or backscattered electrons, which together are also referred to as signal electrons. The embodiments described herein can still be applied for apparatuses and components detecting corpuscles such as secondary and/or backscattered charged particles in the form of electrons or ions, photons, X-rays or other signals in order to obtain a sample image or inspection result.

A “specimen”, “sample” or “wafer” as referred to herein, includes, but is not limited to, semiconductor wafers, semiconductor workpieces, and other workpieces such as memory disks and the like. Embodiments may be applied to any workpiece which is structured, or on which material is deposited. A specimen, a sample, or wafer includes a surface to be imaged and/or structured or on which layers are deposited, an edge, and typically a bevel. According to some embodiments, which can be combined with other embodiments described herein, the apparatus and methods are configured for, or are applied for, critical dimension measurement and defect review applications. Embodiments may also refer to electron beam inspection (EBI), where the microscopes according to embodiments described herein can be beneficially used in light of the desire for high throughput of the named applications. A wafer imaging system or a wafer SEM inspection tool refers to EBI tools, critical dimension (CD) tools or defect review (DR) tools, which are specific tools as understood by a person skilled in the art.

Charged particle beam devices (e.g., electron beam devices, such as scanning electron beam microscopes (SEMs)) usually include one or more magnetic lenses for adapting the characteristics of the charged particle beam. For example, a magnetic lens may be configured to focus the charged particle beam via a magnetic field stemming from the magnetic lens which interacts with the charged particle beam. For a reliable operation of a charged particle beam device, a reliable functioning of the one or more magnetic lenses may be beneficial.

A magnetic lens for a charged particle beam device includes a coil, e.g. a wire arranged in a certain winding arrangement. The coil may be configured for generating the magnetic field of the magnetic lens. For example, the coil of the magnetic lens may be excited with an electrical current, resulting in a magnetic field being generated to adapt the charged particle beam.

A magnetic lens for a charged particle beam device includes a coil carrier configured for fixating a coil of the magnetic lens at a certain position within the magnetic lens. For example, the coil may be arranged within the coil carrier.

The magnetic lens for a charged particle beam includes at least one pole piece. The at least one pole piece may be adapted to guide the magnetic flux towards the lens gap to have a high field strength in the area of the lens gap for focusing the charged particle beam. For example, the at least one pole piece may include a magnetic material and may be arranged at the magnetic lens such that the magnetic field is generated by the coil provided in the gap between the pole pieces.

An aspect of the present disclosure relates to an apparatus for a charged particle beam device, including: a magnetic lens, including: a coil carrier; at least one pole piece; and an electrical insulator configured to electrically insulate the coil carrier and the at least one pole piece from each other. The electrical insulator may be positioned between the coil carrier and the at least one pole piece.

The electrical insulation between the coil carrier and the at least one pole piece may be configured to electrically insulate the at least one pole piece from the coil carrier in a non-defective state of the magnetic lens. In an example, the electrical insulator may at least in part surround the coil carrier. In an example, the electrical insulator may adjoin onto an area of the coil carrier, and/or an area of the at least one pole piece.

In an example, the electrical insulator may include an insulating solid material. In another example, the electrical insulator may include a first part having an insulating solid material and a second part including an insulating gas (e.g., air or another insulating gas).

Due to the electrical insulation via the electrical insulator, the coil carrier and the at least one pole piece may be electrically decoupled from each other. For example, due to the electrical insulation, a change of the electrical potential of the coil carrier may not be translated to a same change of the electrical potential of the at least one pole piece (or vice versa). For example, due to the electrical insulation, a change of the electrical potential of the coil carrier may not evoke a change of the electrical potential at the at least one pole piece.

For example, within charged particle beam devices various electrical potentials or electromagnetic fields may be present, which may cause an electromagnetic noise (e.g. in the form of crosstalk) in some parts of the charged particle beam device. For example, ground loops may be generated which may cause an electromagnetic noise.

The electrical insulation of the coil carrier from the at least one pole piece may alleviate electromagnetic noise at least in part. For example, a liquid-cooling system (e.g. a water-cooling system) of a charged particle beam device may generate electromagnetic noise onto one or more parts of the magnetic lens. The electrical insulation of the coil carrier from the at least one pole piece may also alleviate electromagnetic noise effects stemming from a liquid-cooling system of the charged particle beam, at least in part. For example, the liquid of the liquid-cooling system may provide an electrical connection to ground as the liquid flows through parts of the liquid-cooling system. As described herein, the liquid of the liquid-cooling system may also flow through a conduit system of the coil carrier. The coil carrier may be grounded by the liquid of the liquid cooling system. This can create a ground loop if the coil carrier is electrically connected to the grounded at least one pole piece.

According to some embodiments, which can be combined with other embodiments described herein, the apparatus is configured such that, in a non-defective state of the magnetic lens, the at least one pole piece can be on a set potential, preferably a ground potential of the apparatus. In some examples, the coil carrier may be on a floating potential which may be different than the set potential of the at least one pole piece. Due to the electrical insulator this may result in a potential difference between the coil carrier and the at least one pole piece being present. As mentioned, the electrical insulator can enable an electrical decoupling between the coil carrier and the at least one pole piece. It may thus be achieved that the coil carrier and the at least one pole piece are not on the same electrical potential due to the electrical decoupling. Crosstalk of an electromagnetic noise impinging onto the coil carrier and/or the at least one pole piece may thus be reduced at least in part.

In some examples, the coil carrier may also be actively set on a second set potential, different from the set potential of the at least one pole piece during an operational mode of the magnetic lens.

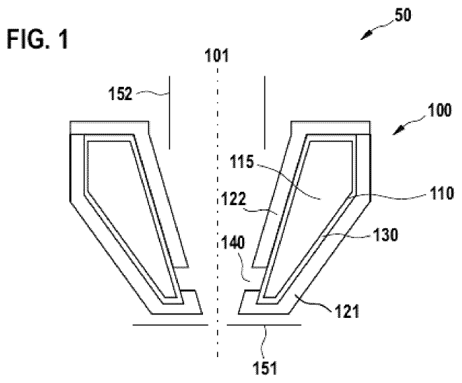

FIG. 1 shows a schematic cross-sectional view of an apparatus for a charged particle beam device according to embodiments of the present disclosure. In FIG. 1 the apparatus includes a lens 50 for a charged particle beam device. The lens 50 may include a magnetic lens 100. For example, the magnetic lens 100 may be integrated into a charged particle beam device as an objective lens. Further, the lens 50 may include an electrostatic lens having an electrode 151 and a further electrode 152.

The magnetic lens 100 may include a coil carrier 110. The coil carrier 110 may be configured to hold one or more coils 115 of the magnetic lens 100. The one or more coils 115 may include a wire arranged in a winding arrangement. By applying an electrical current through the one or more coils 115 a magnetic field may be generated for focusing a charged particle beam of the charged particle device. The one or more coils 115 may be coupled to an electrical power source which may apply the electrical current through the one or more coils 115. A coil of the one or more coils 115, may have a winding number of more than 10, more preferably more than 100, more preferably than 500 turns.

For illustrative purposes an optical axis 101 of the charged particle beam is shown in FIG. 1 along the magnetic lens 100. For example, the optical axis 101 may be the optical axis of a charged particle beam device.

The coil carrier 110 may include an electrically conductive material. In an example, the one or more coils 115 may be electrically insulated from the coil carrier 110. For example, a respective wire of the one or more coils 115 may include an insulating coating material to that regard. In an example, the coil carrier 110 may include an electrically conductive material such that the coil carrier may be set onto a specific set potential by applying an electrical potential to an area of the coil carrier 110, which includes the electrically conductive material.

The magnetic lens 100 may include at least one pole piece. In the embodiment of FIG. 1, the magnetic lens 100 includes a first pole piece 121 and a second pole piece 122. The at least one pole piece (e.g., the first pole piece 121 and the second pole piece 122) may include a magnetic material. The first pole piece 121 and the second pole piece 122 may at least in part surround the coil carrier 110. Between the first pole piece 121 and the second pole piece 122 a gap 140 may be present. The gap 140 between the first pole piece 121 and the second pole piece 122 may be dimensioned to couple a magnetic field induced by the magnetic lens 100 towards the optical axis 101, to adapt the charged particle beam.

The at least one pole piece 121, 122 may include an electrically conductive material. In an example, the at least one pole piece 121, 122 may include an electrically conductive material such that the at least one pole piece 121, 122 may be set or coupled onto a specific set potential, preferably a ground potential, by providing an electrical potential to an area of the at least one pole piece, which includes the electrically conductive material. In an example of the magnetic lens 100, the first pole piece 121 and the second pole piece 122 may be electrically coupled to each other. For example, the first pole piece 121 and the second pole piece 122 may not be electrically insulated from each other. The first pole piece 121 may adjoin the second pole piece 122 over an area (as schematically illustrated in FIG. 1) such that a magnetic and an electrical connection between the first pole piece 121 and the second pole piece 122 is formed. In such a case, when setting the first pole piece 121 to a set potential, the second pole piece 122 will also be set to the set potential due to the electrical coupling between the first pole piece 121 and the second pole piece 122 (or vice versa).

The magnetic lens 100 includes an electrical insulator 130. The electrical insulator 130 may be configured to electrically insulate the coil carrier 110 from the at least one pole piece of the magnetic lens 100. In the example of FIG. 1, the electrical insulator 130 is configured to electrically insulate the coil carrier 110 from the first pole piece 121 and the second pole piece 122. The electrical insulator 130 may enable an electrical decoupling between the coil carrier 110 and the pole pieces 121, 122. As described herein, electromagnetic noise may be affected onto components of the magnetic lens 100. The electrical insulator 130 may enable reducing the effects of the electromagnetic noise at least in part. For example, with the integration of the electrical insulator 130 at the magnetic lens 100, a change in the electrical potential of the coil carrier 110 may affect no, or only a reduced change, in the electrical potential of the first and second pole pieces 121, 122 compared to when no electrical insulator 130 is integrated in the magnetic lens 100.

The electrical insulator 130 may include a dielectric. In an example, the electrical insulator 130 may include a material with a specific electrical resistance higher than 1·10⁹ Ω·m, preferably higher than 1·10¹² Ωm, preferably higher than 1·10¹⁶ Ω·m.

In an example, the electrical insulator 130 may include a material which has a specific electrical resistance, particularly an average specific electrical resistance, which is higher than a (average) specific electrical resistance of an electrically conductive material of the coil carrier 110 by a factor of at least 1·10¹⁵, preferably at least 1·10¹⁷, preferably at least 1·10²⁰.

In an example, the electrical insulator 130 may include a material which has a specific electrical resistance, particularly an average specific electrical resistance, which is higher than a (average) specific electrical resistance of an electrically conductive material of one of the one or more pole pieces 121, 122 of the magnetic lens 100 by a factor of at least 1·10¹⁵, preferably at least 1·10¹⁷, preferably at least 1·10²⁰.

The specific electrical resistance of the herein described parts may be determined e.g., via a simulation, measurements, and/or based on known characteristics of the materials the parts are made of.

An electrical decoupling between two layers may be enhanced if an electrical insulator between the two layers has a higher specific electrical resistance than the two layers. The herein described relations (or values) of the specific electrical resistance of the electrical insulator 130, with respect to the specific electrical resistance of the coil carrier 110, and the at least one pole piece 121, 122 may be beneficial to ensure a reliable isolation which may enable an according decoupling effect. This may reduce at least in part an electromagnetic noise imparted onto the coil carrier 110 and/or the at least one pole piece 121, 122. For example, due to the electrical insulator 130, the at least one pole piece 121, 122 may not be considered to be electrically connected to the coil carrier 110. For example, when the at least one pole piece 121, 122 may be on a ground potential, due to the electrical insulator 130, the coil carrier 110 may not be on the ground potential. Rather the coil carrier 110 may be on a floating potential which, for example, can be different from the ground potential. The electrical insulator 130 may, for example enable that a potential difference between the coil carrier 110 and the at least one pole piece 121, 122 may be present. For example, without an electrical insulator 130, a low resistivity (high conductivity) bridge may be formed between the coil carrier 110 and the at least one pole piece 121, 122. In such a case, when the at least one pole piece 121, 122 would be set onto the ground potential, the coil carrier 110 would also be set onto the ground potential. However, in such a case, a potential change at the coil carrier 110 (e.g., induced by electromagnetic noise) would lead to an according potential change at the at least one pole piece 121,122 (or vice versa). The electrical decoupling via the electrical insulator may enable mitigating such effects, at least in part.

In some examples, the electrical insulator 130 may have material and/or geometrical properties such that a potential difference between the coil carrier 110 and the at least one pole piece 121, 122 being below 100 V, preferably below 500V, more preferably below 1 kV, will not induce a breakdown of the electrical insulator 130.

In an example according to the apparatus of the present disclosure, the lens 50 may include an electrostatic lens. In such a configuration, the lens 50 may include an electrode 151. The electrode 151 can provide a retarding field for focusing of the primary electron beam. According to some embodiments, a further electrode 152 can be provided. The further electrode 152 can provide a potential difference with respect to the electrode 151. The retarding field can be formed between the further electrode 152 and the electrode 151. According to some embodiments, which can be combined with other embodiments described herein, the lens 50 may include an electrostatic lens component having one or more electrodes.

As described above, an aspect relates to an apparatus for a charged particle beam device, including: a magnetic lens, including: a coil carrier; at least one pole piece; and an electrical insulator configured to electrically insulate the coil carrier and the at least one pole piece from each other. The electrical insulator may be positioned between the coil carrier and the at least one pole piece.

In an example, the apparatus may further include: a measurement unit coupled to the coil carrier and the at least one pole piece, and configured to measure at least one electrical characteristic selected from: a resistivity between the coil carrier and the at least one pole piece; a conductance between the coil carrier and the at least one pole piece; a capacitance between the coil carrier and the at least one pole piece; an inductance between the coil carrier and the at least one pole piece.

In an embodiment, which may be combined with other embodiments described herein, the apparatus may be configured to determine a defective state of the magnetic lens based at least in part on the at least one measured electrical characteristic. For example, a defective state (e.g. evoked by a material and/or geometrical change) may alter the at least one electrical characteristic compared to a non-defective state.

For example, in a non-defective state of the magnetic lens, the resistivity between the coil carrier and the at least one pole piece may be in a first resistivity range, whereas in a defective state the resistivity between the coil carrier and the at least one pole piece may be in a second resistivity range different from the first resistivity range. For example, in a non-defective state of the magnetic lens, the conductivity between the coil carrier and the at least one pole piece may be in a first conductivity range, whereas in a defective state the conductivity between the coil carrier and the at least one pole piece may be in a second conductivity range different from the first conductivity range.

For example, in a non-defective state of the magnetic lens, the capacitance between the coil carrier and the at least one pole piece may be in a first capacitance range, whereas in a defective state, the capacitance between the coil carrier and the at least one pole piece may be in a second capacitance range, different from the first capacitance range. For example, in a non-defective state of the magnetic lens, the inductance between the coil carrier and the at least one pole piece may be in a first inductance range, whereas in a defective state, the inductance between the coil carrier and the at least one pole piece may be in a second inductance range, different from the first inductance range.

The differences of the at least one electrical characteristic between the defective and non-defective state may be determined by according experiments (e.g., via provocation experiments and/or based on defective magnetic lenses).

The differences of the at least one electrical characteristic between the defective and non-defective state may also be determined based on calculations or simulations (e.g., based on a simulation of the geometry and/or material of parts of the magnetic lens).

Depending on the value of the at least one measured electrical characteristic with respect to the ranges of the at least one electrical characteristic in the defective state, the defective state of the magnetic lens may be determined.

In an embodiment, which may be combined with other embodiments described herein, the apparatus may be configured to determine the defective state based at least in part on comparing the at least one measured electrical characteristic with a respective predetermined threshold. For example, if the at least one electrical characteristic crosses a respective predetermined threshold, the defective state may be determined. For example, if the at least one electrical characteristic is above (or below) a respective predetermined threshold, the defective state may be determined.

The respective thresholds of the at least one electrical characteristic may be determined by according experiments (e.g., via provocation experiments and/or based on defective magnetic lenses). The respective thresholds of the at least one electrical characteristic between the defective and non-defective state may also be determined based on simulations (e.g., based on a simulation of the geometry and/or material of parts of the magnetic lens).

For example, a resistivity threshold may be predetermined. If the measured resistivity between the coil carrier and the at least one pole piece is below the predetermined resistivity threshold a defective state may be determined. For example, a conductivity threshold may be predetermined. If the measured conductivity between the coil carrier and the at least one pole piece is below the predetermined conductivity threshold a defective state may be determined.

In an embodiment, which may be combined with other embodiments described herein, the apparatus may be configured to determine a water presence at the magnetic lens as the defective state, preferably a water presence between the coil carrier and the at least one pole piece.

For example, the resistivity measurement may be used to determine the undesired water presence at the magnetic lens. Water may change the resistive properties of the electrical insulation between the coil carrier and the at least one pole piece, which may be detected via the resistivity measurement of the measuring unit. The measurement unit may thus be used for checking the magnetic lens of a charged particle beam device.

In an embodiment, which may be combined with other embodiments described herein, the apparatus may be configured to determine a defective state of the magnetic lens, based at least in part on a measured resistivity between the coil carrier and the at least one pole piece, measured by the measurement unit crossing a predetermined threshold indicative of an undesired water presence at the magnetic lens.

In an embodiment, which may be combined with other embodiments described herein, the apparatus may be configured to determine a corrosion at the magnetic lens as the defective state, preferably a corrosion between the coil carrier and the at least one pole piece. For example, the corrosion may result from an undesired water presence at the magnetic lens. For example, a part of the electrical insulator, of the coil carrier, and/or of the at least one pole piece may be corroded due to the undesired water presence.

In an embodiment, which may be combined with other embodiments described herein, the apparatus may be configured to determine a contamination at the magnetic lens as the defective state, preferably a contamination between the coil carrier and the at least one pole piece. For example, the contamination may result from an undesired water presence at the magnetic lens. For example, initially, a water presence may be at the magnetic lens, wherein subsequently at least a part of the water may evaporate. This may leave material residue in that region (e.g., corrosive residue or other material). This residue may change the resistance between the coil carrier and the at least one pole piece which may be measured by the herein described measurement unit.

In an embodiment, which may be combined with other embodiments described herein, the coil carrier may include a first connector for electrically coupling to the measurement unit, and/or the at least one pole piece may include a second connector for electrically coupling to the measurement unit.

In an embodiment, which may be combined with other embodiments described herein, the apparatus may be configured to automatically trigger the measurement of the at least one electrical characteristic and automatically determine the defective state based thereon. A manual intervention by an operator may be minimized.

In an embodiment, which may be combined with other embodiments described herein, the apparatus may be configured to determine the defective state after one or more intervals. For example, the apparatus may be configured to determine the (potential) presence of the defective state once a day, once every two days, once a week, once a month, or once every two months, or in other intervals. This can ensure a monitoring of the defective state of the apparatus over a period of time.

In an embodiment, which may be combined with other embodiments described herein, the apparatus may be configured to trigger a warning and/or block an operational mode of the charged particle beam device if the defective state is determined. The warning may ensure that an operator of the charged electron beam device may be informed about the defective state. The blocking of an operational mode of the charged particle beam devices may ensure that no further (potentially) damaging action may be evoked onto the apparatus and/or the charged particle beam. The operational mode may include an operational mode of the charged particle beam device which requires the use of the objective lens. The operational mode may include an operational mode of the charged particle beam device which requires the use of a water-cooling system for the magnetic lens. For example, if the defective state is determined, the water-cooling system for the magnetic lens may be switched off automatically.

In an embodiment, which may be combined with other embodiments described herein, the coil carrier may include a conduit for a cooling agent for the cooling the magnetic lens. The conduit may be part of a conduit system of the coil carrier. The conduit (or the conduit system) may be configured for a liquid cooling agent (as described herein).

In an embodiment, which may be combined with other embodiments described herein, the apparatus may further include a cooling device for cooling the magnetic lens, the cooling device configured for applying the cooling agent to the conduit.

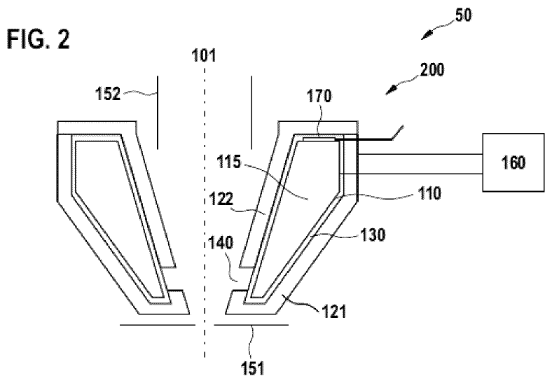

FIG. 2 shows a schematic cross-sectional view of an apparatus according to further embodiments of the present disclosure. In FIG. 2 the apparatus may also include a lens 50 for a charged particle beam device as described in FIG. 1. The lens 50 of FIG. 2 may include a magnetic lens 200. The magnetic lens 200 includes a coil carrier 110, an electrical insulator 130, and at least one pole piece 121, 122. In the illustrated example of FIG. 2 the at least one pole piece 121, 122 may include a first pole piece 121 and a second pole piece 122 as described in FIG. 1. The features and aspects described for the lens 50 of FIG. 1 may also apply for the lens 50 of FIG. 2.

The coil carrier 110 of the herein described magnetic lens 200 may include a conduit 170 for a cooling agent for cooling the magnetic lens 200. The conduit 170 may be for coupling to a cooling system which provides the cooling agent (not shown). The conduit 170 may be configured for a liquid cooling agent (e.g. water). For example, within the coil carrier 110 a conduit system may be integrated such that the cooling agent may thermally interact with the coil carrier 110. The conduit system may, for example, enable that the coil carrier 110 is cooled when the cooling agent is provided within the conduit system by the cooling system. This may enable a cooling of other parts of the magnetic lens 200 due to the thermal coupling of the components. For example, the cooling agent may enable a cooling of the one or more coils within the coil carrier 110 which may heat up due to an electrical current being applied to the one or more coils for generating a magnetic field when operating the magnetic lens 200. For coupling to the cooling system, the coil carrier 110 may include a first cooling port and a second cooling port wherein the first and second cooling port are in communication with the conduit of the coil carrier. For example, the cooling agent may enter the conduit system of the coil carrier 110 via the first cooling port, flow through the conduit system, and may exit the coil carrier 110 via the second cooling port.

The magnetic lens 200 may include a measurement unit 160. The measurement unit 160 may be coupled to the coil carrier 110 and the at least one pole piece 121, 122. In the example of FIG. 2 the measurement unit 160 is coupled to the first pole piece 121 and the coil carrier 110. The measurement unit 160 may be configured to measure an electrical characteristic (e.g. a resistivity) between the coil carrier 110 and the at least one pole piece 121, 122. As described herein, the electrical insulator 130 may have a higher specific electrical resistance than the coil carrier 110 and the at least one pole piece 121, 122. By measuring the resistivity between the coil carrier 110 and the at least one pole piece 121, 122 via the measurement unit 160, the magnetic lens may be analyzed. For example, in a non-defective state the resistivity between the coil carrier 110 and the at least one pole piece 121, 122 should be indicative of a comparatively high resistivity due to the higher resistivity of the electrical insulator 130. A characteristic change in the resistivity between the coil carrier 110 and the at least one pole piece 121, 122 may be indicative of a defective state of the magnetic lens. For example, the resistivity may change due to an undesired water presence occurring at or within the magnetic lens.

In an example, the measured resistivity between the coil carrier 110 and the at least one pole piece 121, 122 may enable detection of water that has entered inside of the magnetic lens 200. For example, a water presence in the lens may change the resistivity between the coil carrier 110 and the at least one pole piece 121, 122. An undesired water presence may be induced at various parts of the magnetic lens 200 for various reasons.

In some examples, a risk of an undesired water presence may stem from the liquid cooling agent which may flow through the conduit system of the coil carrier 110. For example, a malfunctioning or defect of the cooling system or of the coil carrier may not always be excluded. In such a case, an undesired water presence may occur at one or more areas of the magnetic lens due to a leakage of the cooling system (e.g., at one or more areas of the coil carrier 110, the electrical insulator 130 and/or the at least one pole piece 121, 122).

An undesired water presence may also occur in embodiments which are not necessarily for coupling to a cooling system or not coupled to a cooling system (e.g., embodiments not including a conduit for a cooling agent). For example, a risk of an undesired water presence may also stem from other parts of the charged particle beam device the magnetic lens is integrated into. For example, a liquid-cooling system may be connected to other parts of the charged particle beam device (e.g., to other lenses or electronic parts). A water leakage may result from such a liquid-cooling system, which may lead to an undesired water presence at the magnetic lens. In another example, water may spill during a maintenance procedure, e.g., when parts are being replaced and/or tubes are disconnected. Water (or other liquids) might also be introduced to the magnetic lens during a cleaning activity of the charged particle beam device. A water leakage may also be unrelated to the charged particle beam device itself (e.g., due to external influences or samples within the charged particle beam device).

The herein described concepts may enable monitoring of such an undesired water presence.

As mentioned, an undesired water presence may be evoked at one or more areas of the coil carrier 110, at the electrical insulator 130 and/or at the at least one pole piece 121, 122. The undesired water presence may alter the material and/or geometrical properties at the one or more areas of the coil carrier 110, the electrical insulator 130 and/or the at least one pole piece 121, 122. For example, the undesired water presence may affect a material change due to corrosion of the affected material. Also, the undesired water presence may add a water concentration to the one or more areas of the coil carrier 110, the electrical insulator 130, and/or the at least one pole piece 121, 122.

The undesired water presence may reduce the resistivity between the coil carrier 110 and the at least one pole piece 121, 122 compared to the resistivity between the coil carrier 110 and the at least one pole piece 121, 122 in a non-defective state.

By measuring the resistivity between the coil carrier 110 and the at least one pole piece 121, 122 with the measurement unit 160 a suspicious resistivity change may be determined indicative of an undesired water presence within the magnetic lens 200.

The measurement unit 160 may be part of an analysis unit (not shown). For example, the analysis unit may analyze based on the resistivity measured by the measurement unit 160 if an undesired water presence at the magnetic lens 200 has occurred. For example, the analysis unit may determine a defective state of the magnetic lens based at least in part on the measured resistivity between the coil carrier 110 and the at least one pole piece 121, 122 (as described herein).

The measurement unit 160 may be communicatively coupled to one or more parts of the analysis unit. For example, the analysis unit may include a computing unit, such as a controller, which may perform the according computational operations for determining the defective state.

In an example, the measurement unit 160 may be communicatively coupled to the computing unit of the analysis unit. The measurement unit 160 may communicate the measured data to the computing unit wherein the computing unit may then perform the according computational operations to determine the defective state (e.g. a water presence) based on the measured data. For example, the computing unit may also trigger a measurement of the resistivity (or the at least one electrical characteristic, as described herein) between the coil carrier 110 and the at least one pole piece 121, 122 which may be used for determining the defective state of the magnetic lens.

The computing unit of the analysis unit may include one or more processors for carrying out computational operations. The computing unit may further include one or more non-transitory storage media for storing of data and/or computational instructions. The computing unit may also include one or more communication ports for communicatively coupling to the measurement unit.

A controller can include a central processing unit (CPU), a memory, and for example, support circuits. To facilitate control of the apparatus for analyzing a magnetic lens for a charged particle beam device, the CPU may be one of any form of general purpose computer processor that can be used in an industrial setting for controlling various components of a charged particle beam device and sub-processors, for example a measurement unit coupled to the coil carrier and the at least one pole piece. The memory is coupled to the CPU. The memory, or a computer readable medium, may be one or more readily available memory devices such as random access memory, read only memory, hard disk, or any other form of digital storage either local or remote. The support circuits may be coupled to the CPU for supporting the processor in a conventional manner. These circuits include cache, power supplies, clock circuits, input/output circuitry and related subsystems, and the like. Inspecting process instructions are generally stored in the memory as a software routine typically known as a recipe. The software routine may also be stored and/or executed by a second CPU (not shown) that is remotely located from the hardware being controlled by the CPU. The software routine, when executed by CPU, transforms the general purpose computer into a specific purpose computer (controller) that controls the apparatus operation, such as that for analyzing a magnetic lens for a charged particle beam device. Although the method and/or process of the present disclosure is discussed as being implemented as a software routine, some of the method steps that are disclosed therein may be performed in hardware as well as by the software controller. As such, embodiments of the disclosure may be implemented in software as executed upon a computer system, and hardware as an application specific integrated circuit or other type of hardware implementation, or a combination of software and hardware.

The controller may execute or perform a method of analyzing a magnetic lens for a charged particle beam device according to embodiments of the present disclosure. According to an embodiment, and apparatus for a charged particle beam device executing any of the methods described herein is provided. The apparatus may include the controller. The controller includes a processor and a memory, storing instructions that, when executed by the processor, cause the apparatus to perform a method according to embodiments of the present disclosure.

In an example, when a water presence is detected by the analysis unit (based on the measurement of the measurement unit 160) the analysis unit may trigger a warning (e.g., via an output signal) which may inform an operator. For example, the computing unit of the analysis unit may be communicatively coupled to an output device of the charged particle beam device including the apparatus such that the charged particle beam device may output the warning based on the communicated output signal. This may enable performing a maintenance early on which may prevent further undesired effects inside the magnetic lens due to the detected water presence. The herein described concepts may thus improve the reliability of a magnetic lens and/or of a charged particle beam device including the herein described apparatus.

In an example, when a water presence is detected by the analysis unit (based on the measurement of the measurement unit 160) the analysis unit may send a control message to the charged particle beam device (e.g., to a control unit of the charged particle beam device) which triggers switching off the water supply of the water-cooling system provided to the magnetic lens and/or other liquid-cooling systems of the charged particle beam device. Additionally, the analysis unit may also trigger the warning which may inform an operator (as described herein).

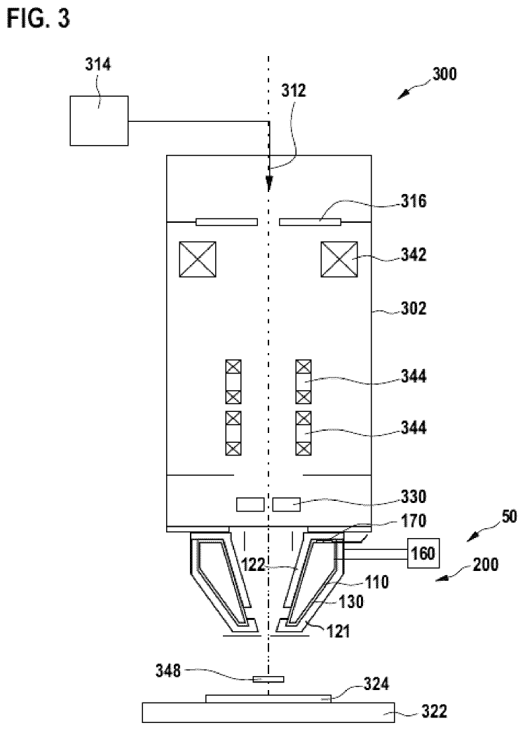

A further aspect relates to a charged particle beam device including an embodiment of the apparatus according to the present disclosure. The charged particle beam device may include a scanning electron beam microscope (e.g., as described herein with respect to FIG. 3).

In an embodiment, which may be combined with other embodiments described herein, the apparatus according to the present disclosure is configured as an objective lens of the charged particle beam device according to the present disclosure.

In an embodiment, which may be combined with other embodiments described herein, the charged particle device of the present disclosure may include the herein described analysis unit for determining the defective state of the magnetic lens.

FIG. 3 shows a schematic cross-sectional view of a charged particle beam device 300 including a magnetic lens, according to embodiments of the present disclosure. For example, the charged particle beam device may include the apparatus described with respect to FIG. 1 and FIG. 2 integrated as a lens 50. In FIG. 3, the herein described apparatus includes the lens 50 as described with respect to FIG. 2 having the magnetic lens 200. For FIG. 3, the lens 50 is integrated as an objective lens of the charged particle beam device 300.

The charged particle beam device 300 may include a SEM (scanning electron microscope) imaging apparatus. For example, the SEM imaging apparatus may be configured as a wafer imaging system. An electron beam column of the charged particle beam device 300, e.g. column 302, may include a first chamber, a second chamber and a third chamber. The first chamber, which can also be referred to as a gun chamber, may include an electron beam source 312 with an emitter and, for example, a suppressor.

According to embodiments described herein, the emitter may be connected to a power supply 314 for providing a voltage to the emitter. The potential provided to the emitter may be such that the electron beam is accelerated to an energy of 12 keV or above. Accordingly, the emitter may be biased to a potential of −12 kV or higher negative voltages. As described herein, having the emitter on a negative potential may have the benefits that the column and the beam guiding tube can be at ground or at a moderate potential. According to alternative embodiments, which can be combined with other embodiments described herein, the emitter can be on ground or on a potential close to ground and components in the column can be biased to a positive potential.

An electron beam is generated by the electron beam source 312. In the example of FIG. 3, the beam is aligned to a beam limiting aperture 316, which is dimensioned to shape the beam. For example, the beam limiting aperture may block a portion of the beam. The beam may then pass through the one or more of the chambers of the column 302. The primary electron beam may be focused on the sample (e.g. a wafer or specimen) by an objective lens, which may act as the magnetic lens 200 described herein. The sample may be positioned on a sample position on the sample stage 322. On impingement of the electron beam, for example, secondary or backscattered electrons may be released from the sample 324. The detector 330 may detect signal electrons for image generation of the area of the sample scanned by the primary electron beam.

According to some embodiments, which can be combined with other embodiments described herein, a condenser lens 342 may be provided. A two-stage deflection system 344 can be provided downstream of the condenser lens. A deflection system, such as the two-stage deflection system 344 can align the primary charged particle beam to the optical axis of the objective lens.

As shown in FIG. 3 (and in FIG. 1 and FIG. 2), the magnetic lens 200 may include at least one pole piece 121, 122 and a coil carrier 110 having at least one coil. The magnetic lens 200 may include an electrical insulator 130 configured for electrically insulating the at least one pole piece 121, 122 and the coil carrier 110 from each other (as described herein). The magnetic lens 200 may be configured for focusing the charged particle beam on the sample 324. Further, an electrostatic lens component can be provided by one or more electrodes (as described with respect to FIG. 1 and FIG. 2).

In an embodiment, which may be combined with other embodiments described herein, the charged particle beam device 300 may include the herein described measurement unit 160. Furthermore, the charged particle beam device 300 may include the herein described analysis unit (not shown). The herein described concepts for the apparatus of the present disclosure may therefore, also be applied to the charged particle beam device, including the apparatus of the present disclosure.

It is desired in some applications that the number of electrons impinging on the sample equals the amount released or leaving the sample. Charging of the sample can be reduced or avoided. However, positive or negative sample charging can also be achieved by appropriate control voltages in combination with suitable landing energies, in the case in which sample charging is desired by the application. Accordingly, the sample charging can be controlled, e.g. via charging of the sample stage 322.

Further, a scanning deflector assembly may be provided. The scanning deflector assembly can, for example, be a magnetic scanning deflector assembly. An electrostatic scanning deflector assembly or an electrostatic scanning deflector component, which is a portion of the scanning deflector assembly, can be provided and may be configured for high pixel rates. For example, magnetic scanning and electrostatic scanning can be combined. According to typical embodiments, which can be combined with other embodiments described herein, the scanning deflector assembly can be a single stage assembly. Alternatively, a two-stage or even a three-stage deflector assembly can also be provided. Each stage may be provided at a different position along the optical axis of the charged particle beam device.

According to some embodiments, a proxy electrode 348 can be provided. For example, the proxy electrode 348 can be provided between the objective lens and the sample stage 322. In some embodiments, the proxy electrode 348 may not be provided and/or the electrode 151 may serve as a proxy electrode.

The charged particle beam device as shown in FIG. 3 may include a detector 330. The detection element or detector 330 can include e.g. a scintillator, pin diode, or other electron sensitive devices.

A further aspect relates to a method of analyzing a magnetic lens for a charged particle beam device including, measuring at least one electrical characteristic selected from: a resistivity between a coil carrier and at least one pole piece from the magnetic lens; a conductance between the coil carrier and the at least one pole piece from the magnetic lens; a capacitance between the coil carrier and the at least one pole piece from the magnetic lens; an inductance between the coil carrier and the at least one pole piece from the magnetic lens.

The measuring of the at least one electrical characteristic may include applying a current and/or a voltage between the coil carrier and the at least one pole piece.

In an embodiment, which may be combined with other embodiments described herein, the method may include determining a defective state of the magnetic lens based at least in part on the at least one measured electrical characteristic (as described herein).

In an embodiment, which may be combined with other embodiments, the method of analyzing may not necessarily include the measuring of the at least one electrical characteristic. In such a case the method may, however, rely on the at least one electrical characteristic being measured and provided as an input to the method. For example, a computing unit may not itself measure the at least one electrical characteristic. However, the measured at least one electrical characteristic may be an input to the computing unit which may then perform the herein described method of the second aspect.

In an embodiment, which may be combined with other embodiments described herein, the determining of the defective state may include comparing the at least one measured electrical characteristic with a respective predetermined threshold (as described herein).

The herein described method may be used to analyze the magnetic lens of the apparatus of the present disclosure.

In another example, the herein described method may be used to analyze an apparatus having a magnetic lens, the magnetic lens not necessarily including the electrical insulator to electrically insulate a coil carrier from at least one pole piece. The herein described aspects of determining a defective state of the magnetic lens based at least in part on the at least one measured electrical characteristic may also be applicable for such apparatuses. For example, an electrical resistivity between a coil carrier and at least one pole piece of a magnetic lens having no electrical insulator for electrically insulating the coil carrier from the at least one pole piece may also change in a defective state, which may be detected by according measurements (as described herein).

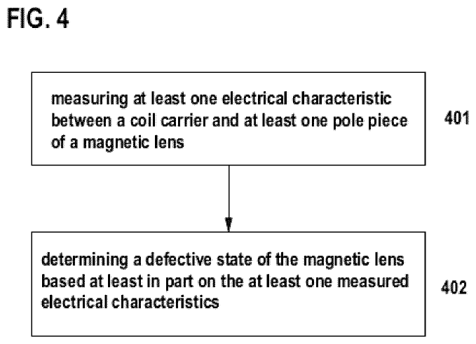

FIG. 4 shows a block diagram of a method for analyzing a magnetic lens of a charged particle beam device according to an embodiment of the present disclosure. The method may include measuring 401 at least one electrical characteristic, for example a resistivity, between the coil carrier 110 and the at least one pole piece 121, 122 of the magnetic lens 100 (or magnetic lens 200).

The method may further include determining 402 a defective state of the magnetic lens 100 (or the magnetic lens 200) based at least in part on the at least one measured electrical characteristic (e.g., the resistivity between the coil carrier 110 and the at least one pole piece). The method may be carried out by the herein described analysis unit (e.g., including the measurement unit 160 and a computing unit).

A further aspect relates to a non-transitory medium including instructions, that, when executed by one or more processors, cause the processors (or a charged particle beam device of the present disclosure including the one or more processors) to perform a method according to the present disclosure. For example, the computing unit including one or more processors may trigger the measurement of the at least one electrical characteristic between the coil carrier and the at least one pole piece and/or, determine the defective state based on the measured at least one electrical characteristic (as described herein). A further aspect also relates to a computer program for carrying out a method of the present disclosure.

For example, the charged particle beam device according to the disclosure may include (or be communicatively coupled to) the non-transitory medium according to the present disclosure. The herein described computing unit including one or more processers may have access to the non-transitory medium to perform the method according to the third aspect. The herein described charged particle beam device may thus be configured to carry out the herein described method.

Notably, features and aspects described herein with respect to an apparatus or device may also be accordingly applicable to the herein described methods or computer programs (and vice versa).

Subsequently, embodiments according to the present disclosure are described.

Embodiment 1: An apparatus for a charged particle beam device, comprising: a magnetic lens, comprising: a coil carrier; at least one pole piece; and an electrical insulator configured to electrically insulate the coil carrier and the at least one pole piece from each other.
Embodiment 2: The apparatus according to embodiment 1, further comprising: a measurement unit coupled to the coil carrier and the at least one pole piece, and configured to measure at least one electrical characteristic selected from: a resistivity between the coil carrier and the at least one pole piece; a conductance between the coil carrier and the at least one pole piece; a capacitance between the coil carrier and the at least one pole piece; an inductance between the coil carrier and the at least one pole piece.
Embodiment 3: The apparatus according to embodiment 2, wherein the apparatus is configured to determine a defective state of the magnetic lens based at least in part on the at least one measured electrical characteristic.
Embodiment 4: The apparatus according to embodiment 2 or 3, wherein the apparatus is configured to determine the defective state based at least in part on comparing the at least one measured electrical characteristic with a respective predetermined threshold.
Embodiment 5: The apparatus according to any of embodiments 2-4, the coil carrier comprising a first connector for electrically coupling to the measurement unit, and the at least one pole piece comprising a second connector for electrically coupling to the measurement unit.
Embodiment 6: The apparatus according to any of embodiments 3-5, being configured to trigger a warning and/or block an operational mode of the charged particle beam device if the defective state is determined.
Embodiment 7: The apparatus according to any of embodiments 1-6, the coil carrier comprising a conduit for a cooling agent for cooling the magnetic lens.
Embodiment 8: The apparatus according to embodiment 7, further comprising a cooling device for cooling the magnetic lens, the cooling device configured for applying the cooling agent to the conduit.
Embodiment 9: The apparatus according to any of embodiments 1-8, the electrical insulator comprising an insulating solid material.
Embodiment 10: A charged particle beam device comprising: an apparatus according to any of embodiments 1-9.
Embodiment 11: A method of analyzing a magnetic lens for a charged particle beam device, comprising: measuring at least one electrical characteristic selected from: a resistivity between a coil carrier and at least one pole piece from the magnetic lens; a conductance between the coil carrier and the at least one pole piece; a capacitance between the coil carrier and the at least one pole piece; and an inductance between the coil carrier and the at least one pole piece.
Embodiment 12: The method according to embodiment 11, further comprising: determining a defective state of the magnetic lens based at least in part on the at least one measured electrical characteristic.
Embodiment 13: The method according to embodiment 12, the determining of the defective state comprising: comparing the at least one measured electrical characteristic with a respective predetermined threshold.
Embodiment 14: Non-transitory medium comprising instructions, that, when executed, cause one or more processors to perform a method according to any of embodiments 11-13.

While the foregoing is directed to embodiments, other and further embodiments may be devised without departing from the basic scope, and the scope thereof is determined by the claims that follow.

What is claimed is:

1. An apparatus for a charged particle beam device, comprising:
a magnetic lens, comprising:
a coil carrier;
at least one pole piece; and
an electrical insulator configured to electrically insulate the coil carrier and the at least one pole piece from each other.

2. The apparatus according to claim 1, further comprising:
a measurement unit coupled to the coil carrier and the at least one pole piece, and configured to measure at least one electrical characteristic selected from:
a resistivity between the coil carrier and the at least one pole piece;
a conductance between the coil carrier and the at least one pole piece;
a capacitance between the coil carrier and the at least one pole piece; or
an inductance between the coil carrier and the at least one pole piece.

3. The apparatus according to claim 2, wherein the apparatus is configured to determine a defective state of the magnetic lens based at least in part on the at least one measured electrical characteristic.

4. The apparatus according to claim 2, wherein the apparatus is configured to determine a defective state based at least in part on comparing the at least one measured electrical characteristic with a respective predetermined threshold.

5. The apparatus according to claim 3, wherein the apparatus is configured to determine the defective state based at least in part on comparing the at least one measured electrical characteristic with a respective predetermined threshold.

6. The apparatus according to claim 2, the coil carrier comprising a first connector for electrically coupling to the measurement unit, and the at least one pole piece comprising a second connector for electrically coupling to the measurement unit.

7. The apparatus according to claim 3, being configured to trigger a warning and/or block an operational mode of the charged particle beam device if the defective state is determined.

8. The apparatus according to claim 4, being configured to trigger a warning and/or block an operational mode of the charged particle beam device if the defective state is determined.

9. The apparatus according to claim 1, the coil carrier comprising a conduit for a cooling agent for cooling the magnetic lens.

10. The apparatus according to claim 9, further comprising a cooling device for cooling the magnetic lens, the cooling device configured for applying the cooling agent to the conduit.

11. The apparatus according to claim 1, the electrical insulator comprising an insulating solid material.

12. A charged particle beam device comprising:
an apparatus, comprising:
a magnetic lens, comprising:
a coil carrier;
at least one pole piece; and
an electrical insulator configured to electrically insulate the coil carrier and the at least one pole piece from each other.

13. The charged particle beam device according to claim 12, the apparatus further comprising:
a measurement unit coupled to the coil carrier and the at least one pole piece, and configured to measure at least one electrical characteristic selected from:
a resistivity between the coil carrier and the at least one pole piece;
a conductance between the coil carrier and the at least one pole piece;
a capacitance between the coil carrier and the at least one pole piece; or
an inductance between the coil carrier and the at least one pole piece.

14. The charged particle beam device according to claim 13, the apparatus being configured to determine a defective state of the magnetic lens based at least in part on the at least one measured electrical characteristic.

15. A method of analyzing a magnetic lens for a charged particle beam device, comprising:
measuring at least one electrical characteristic selected from:
a resistivity between a coil carrier and at least one pole piece from the magnetic lens;
a conductance between the coil carrier and the at least one pole piece;
a capacitance between the coil carrier and the at least one pole piece; and
an inductance between the coil carrier and the at least one pole piece.

16. The method according to claim 15, further comprising:
determining a defective state of the magnetic lens based at least in part on the at least one measured electrical characteristic.

17. The method according to claim 16, the determining of the defective state comprising:
comparing the at least one measured electrical characteristic with a respective predetermined threshold.

18. The method according to claim 16, further comprising:
triggering a warning and/or blocking an operational mode of the charged particle beam device if the defective state is determined.

19. A non-transitory medium comprising instructions, that, when executed, causes one or more processors to perform a method of analyzing a magnetic lens for a charged particle beam device, comprising:
measuring at least one electrical characteristic selected from:
a resistivity between a coil carrier and at least one pole piece from the magnetic lens;
a conductance between the coil carrier and the at least one pole piece;
a capacitance between the coil carrier and the at least one pole piece; and
an inductance between the coil carrier and the at least one pole piece.

20. The non-transitory medium according to claim 19, the non-transitory medium further comprising instructions, that, when executed, cause the one or more processors to:
determine a defective state of the magnetic lens based at least in part on the at least one measured electrical characteristic.
